(19) United States
(12) Patent Application Publication
(10) Pub. No.: US 2007/0200053 A1
(43) Pub. Date: Aug. 30, 2007

(54) Image pickup apparatus, camera module, electronic device, and fabrication method for image pickup apparatus

(75) Inventors: Takumi Nomura, Aichi (JP); Hitoshi Shibuya, Saitama (JP)

Correspondence Address: LERNER, DAVID, LITTENBERG,;KRUMHOLZ & MENTLIK, 600 SOUTH AVENUE WEST, WESTFIELD, NJ, 07090, US

(73) Assignee: Sony Corporation, Tokyo (JP)

(21) Appl. No.: 11/701,525

(22) Filed: Feb. 1, 2007

(30) Foreign Application Priority Data
Feb. 2, 2006 (JP) P2006-025779

(51) Int. Cl. H01L 33/00

(52) U.S. Cl. 250/206; 257/79; 348/E05.028

(57) ABSTRACT

An image pickup apparatus may include a wiring board; a frame member having a framework-like shape and disposed on the wiring board, an image pickup element disposed on the inner side of the frame member on the wiring board, and a transparent cover disposed on the frame member. The wiring board and the frame member may be attached to each other by thermosetting adhesive. The frame member may be made of a material which has a coefficient of thermal expansion lower than that of the wiring board and has a rigidity higher than that of the wiring board.

### CROSS-REFERENCE TO RELATED APPLICATIONS

This application claims priority from Japanese Patent Application No. JP 2006-025779 filed with the Japanese Patent Office on Feb. 2, 2006, the entire content of which is incorporated herein by reference.

### BACKGROUND OF THE INVENTION

This invention relates to an image pickup apparatus, a camera module, an electronic device, and a fabrication method for an image pickup apparatus.

In recent years, electronic device in which an image pickup apparatus is incorporated such as portable telephone sets and PDAs (Personal Digital Assistants) have been provided.

An image pickup apparatus for use with such electronic device is disclosed, for example, in Japanese Patent Laid-open No. 2005-101306 (hereinafter referred to as Patent Document 1). The image pickup apparatus disclosed in Patent Document 1 includes a wiring board, and a frame member having a framework-like shape and disposed on the wiring board. The image pickup apparatus further includes an image pick element disposed on the inner side of the frame member on the wiring board, and a transparent cover disposed on the frame member. The frame member is secured by adhesion to the wiring board using a thermosetting adhesive.

However, in the image pickup apparatus in related art, if the wiring board is formed with a small thickness from a material having low rigidity in order to achieve miniaturization, reduction in thickness and reduction in weight, then warpage or twist is likely to occur with the wiring board upon adhesion. Such warpage or twist gives rise to such disadvantages as distortion of the image pickup element, deterioration of the wire bonding performance and deterioration of the soldering performance of the wiring board.

### SUMMARY OF THE INVENTION

Therefore, it is demanded to provide an image pickup apparatus, a camera module, an electronic device, and a fabrication method for an image pickup apparatus by which enhancement of the reliability, miniaturization, reduction in thickness and reduction in weight can be achieved advantageously.

According to an embodiment of the present invention, there is provided an image pickup apparatus which may include a wiring board, a frame member, an image pickup element and a transparent cover. The frame member may have a framework-like shape and disposed on the wiring board. The image pickup element may be disposed on the inner side of the frame member on the wiring board. The transparent cover may be disposed on the frame member. The wiring board and the frame member may be attached to each other by thermosetting adhesive. The frame member may be made of a material which has a coefficient of thermal expansion lower than that of the wiring board and has a rigidity higher than that of the wiring board.

According to another embodiment of the present invention, there is provided a camera module which may include a lens barrel, a base plate, an image pickup apparatus, and a signal processing section. The lens barrel may be configured to hold an image pickup optical system. The base plate may be attached to the lens barrel. The image pickup apparatus may be incorporated in the lens barrel and configured to pick up an image of an image pickup object formed by the image pickup optical system and output an image pickup signal. The signal processing section may be provided on the base plate and configured to receive the image pickup signal outputted from the image pickup apparatus as an input and perform a predetermined signal process for the received image pickup signal. The image pickup apparatus may include a wiring board, a frame member, an image pickup element, and a transparent cover. The frame member has a framework-like shape and disposed on the wiring board. The image pickup element may be disposed on the inner side of the frame member on the wiring board. The transparent cover may be disposed on the frame member. The wiring board and the frame member may be attached to each other by a thermosetting adhesive. The frame member may be made of a material which has a coefficient of thermal expansion lower than that of the wiring board and has a rigidity higher than that of the wiring board.

According to a further embodiment of the present invention, there is provided an electronic device which may include a housing, and a camera module incorporated in the housing. The camera module includes a lens barrel, a base plate, an image pickup apparatus, and a signal processing section. The lens barrel may be configured to hold an image pickup optical system. The base plate may be attached to the lens barrel. The image pickup apparatus may be incorporated in the lens barrel and configured to pick up an image of an image pickup object formed by the image pickup optical system and output an image pickup signal. The signal processing section may be provided on the base plate and configured to receive the image pickup signal outputted from the image pickup apparatus as an input and perform a predetermined signal process for the received image pickup signal. The image pickup apparatus may include a wiring board, a frame member, an image pickup element, and a transparent cover. The frame member has a framework-like shape and disposed on the wiring board. The image pickup element may be disposed on the inner side of the frame member on the wiring board. The transparent cover may be disposed on the frame member. The wiring board and the frame member may be attached to each other by a thermosetting adhesive. The frame member may be made of a material which has a coefficient of thermal expansion lower than that of the wiring board and has a rigidity higher than that of the wiring board.

According to a still further embodiment of the present invention, there is provided a fabrication method for an image pickup apparatus which may include a wiring board, a frame member, an image pickup element, and a transparent cover. The frame member may have a framework-like shape and disposed on the wiring board. The image pickup element may be disposed on the inner side of the frame member on the wiring board. The transparent cover may be disposed on the frame member. The wiring board and the frame member may be attached to each other by thermosetting adhesive. The fabrication method may include the steps of forming the frame member from a material which has a coefficient of thermal expansion lower than that of the wiring board and has a rigidity higher than that of the wiring board, and placing the frame member on the wiring board with the thermosetting adhesive interposed and heating the frame member in this state to harden the thermosetting adhesive.

With the image pickup apparatus, camera module, electronic device, and fabrication method for an image pickup apparatus, even if a material having a small thickness and a low rigidity is used for the wiring board of the image pickup apparatus, flatness of the wiring board may be obtained without suffering from warpage or twist. This is advantageous in achievement of reduction of distortion of the image pickup element, assurance of enhancement of the wire bonding performance, and enhancement of the soldering coupling performance and also in enhancement of the reliability, miniaturization, reduction in thickness and reduction in weight of the image pickup apparatus.

### BRIEF DESCRIPTION OF THE DRAWINGS

FIG. 1A is a front elevational view and FIG. 1B is a perspective view, showing an example of a portable telephone set in which a camera module is incorporated;

FIGS. 2 and 3 are exploded perspective views of the camera module;

FIG. 4 is a cross sectional view of the camera module;

FIG. 5A is a plan view of an image pickup apparatus, FIG. 5B is a cross sectional view taken along line B-B of FIG. 5A, FIG. 5C is a cross sectional view taken along line C-C of FIG. 5A, and FIG. 5D is a perspective view as viewed in the direction indicated by D in FIG. 5A;

FIGS. 6A to 6I are views illustrating different steps of a fabrication method for the image pickup apparatus;

FIG. 7 is a view illustrating a principle when a frame member and an image pickup device are secured by adhesion to a wiring board using a thermosetting adhesive; and

FIGS. 8A to 8J are views illustrating different steps of another fabrication method for the image pickup apparatus.

### DETAILED DESCRIPTION

A preferred embodiment of the present invention is described below with reference to the accompanying drawings.

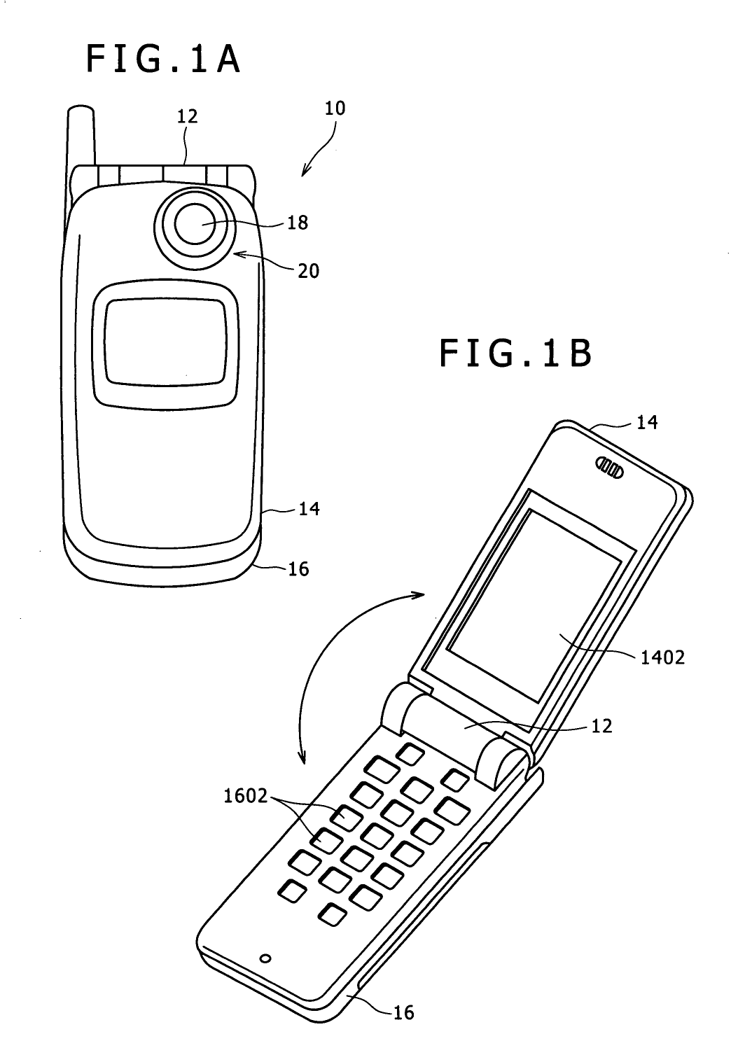

FIGS. 1A and 1B show an appearance of a portable telephone set 10 which is an electronic device in which a camera module is incorporated.

Referring to FIGS. 1A and 1B, the portable telephone set 10 shown includes first and second housings 14 and 16 connected for rocking motion relative to each other by a hinge member 12.

A liquid crystal display panel 1402 is provided on an inner face of the first housing 14 while operation switches 1602 such as ten keys and function keys are provided on an inner face of the second housing 16.

The camera module 20 is incorporated at a base end portion of the first housing 14, and an image picked up by the camera module 20 is displayed on the liquid crystal display panel 1402.

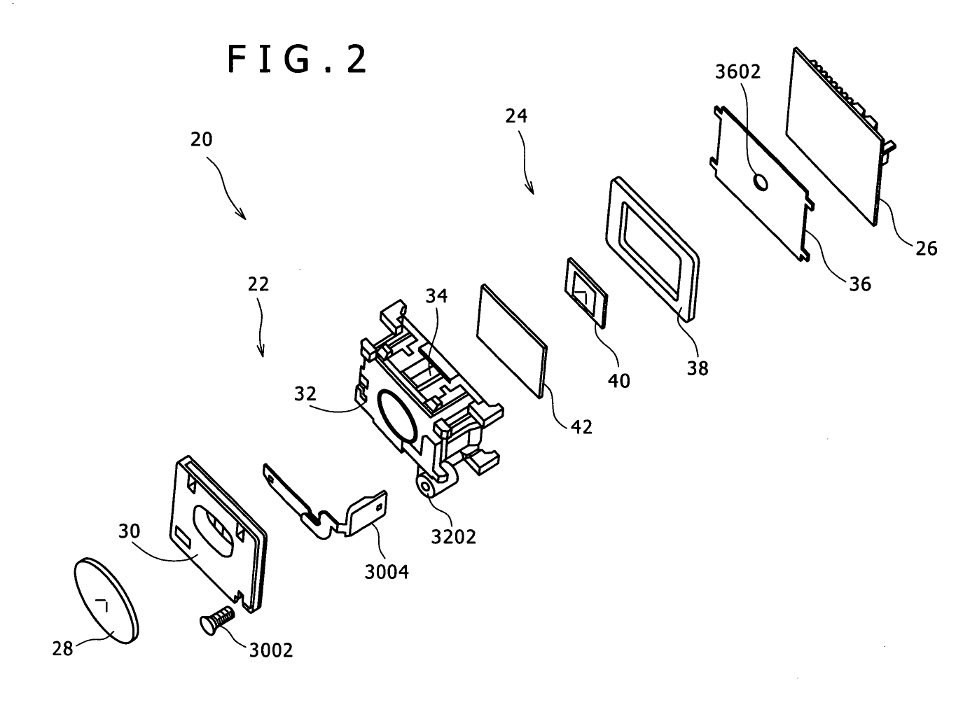

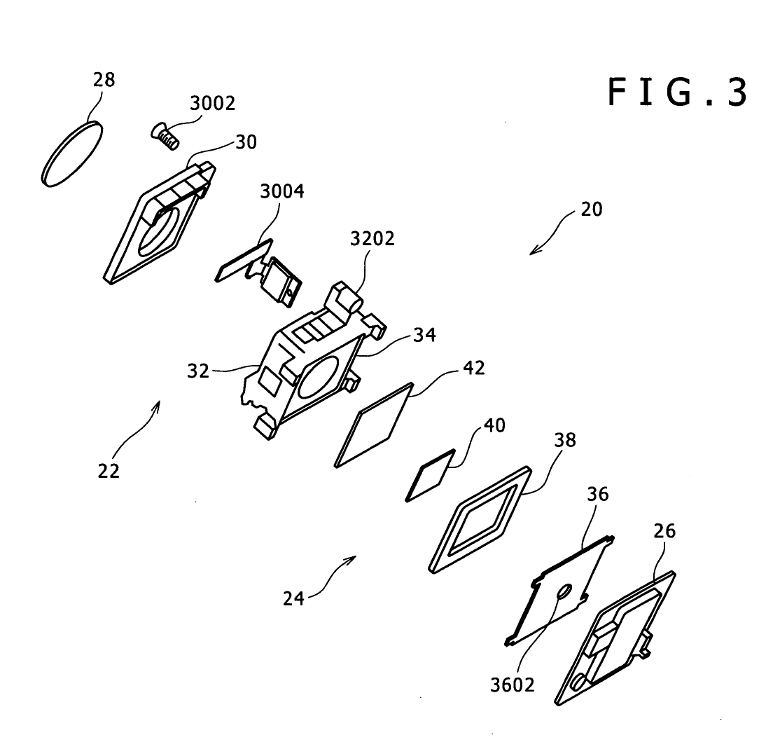

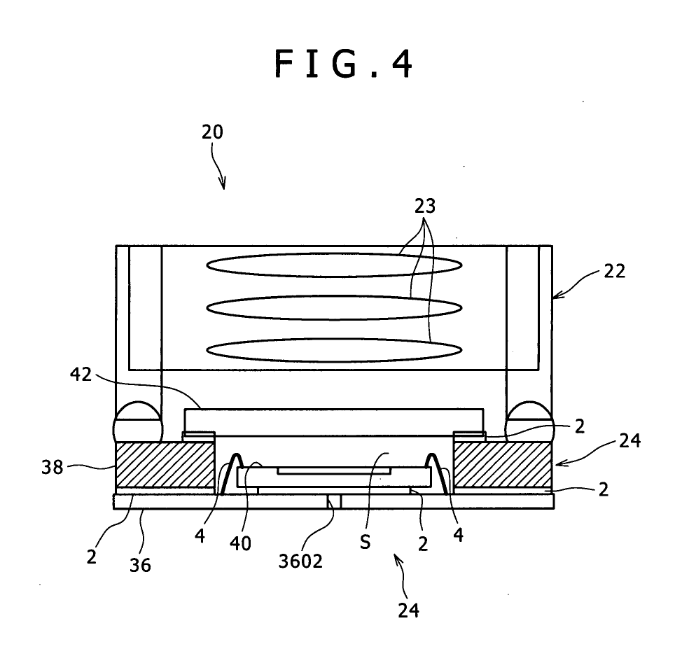

FIGS. 2 and 3 show the camera module 20 in an exploded perspective view, and FIG. 4 shows a cross sectional view of the camera module 20.

Referring to FIGS. 2 to 4, the camera module 20 includes a lens barrel 22, an image pickup apparatus 24, and a base plate 26.

The lens barrel 22 holds an image pickup optical system 23 thereon and has a front end and a rear end at the opposite locations thereof along an optical axis of the image pickup optical system 23. An optical member 28 which composes the image pickup optical system 23 is disposed most forwardly such that it is exposed to the front end of the lens barrel 22. The optical member 28 in the present embodiment is a lens cover.

The lens barrel 22 has a form of a rectangular plate and has an accommodating space provided at a central portion thereof. The accommodating space extends in the forward and backward direction through the lens barrel 22, or in other words, extends along the optical axis of the image pickup optical system 23.

The lens barrel 22 includes a shutter supporting housing 30, a front lens barrel 32 and a rear lens barrel 34 assembled in an overlapping relationship to each other along the direction of the optical axis of the image pickup optical system 23.

A shutter not shown for opening and closing an aperture for an optical path of the image pickup optical system 23 and a shutter driving mechanism are provided at a central portion of the shutter supporting housing 30. The shutter supporting housing 30 is coupled to a boss 3202 of the front lens barrel 32 by means of a screw 3002.

A flexible board 3004 is provided for controlling the shutter driving mechanism mentioned above.

The image pickup apparatus 24 picks up an image of an image pickup object formed by the image pickup optical system 23 and outputs an image pickup signal. The image pickup apparatus 24 is provided on the base plate 26 and attached to a rear end of the rear lens barrel 34 together with the base plate 26 as seen in FIGS. 2 and 3.

The base plate 26 has a signal processing section which receives an image pickup signal outputted from the image pickup apparatus 24 as an input thereto and performs a predetermined signal process for the received image pickup signal.

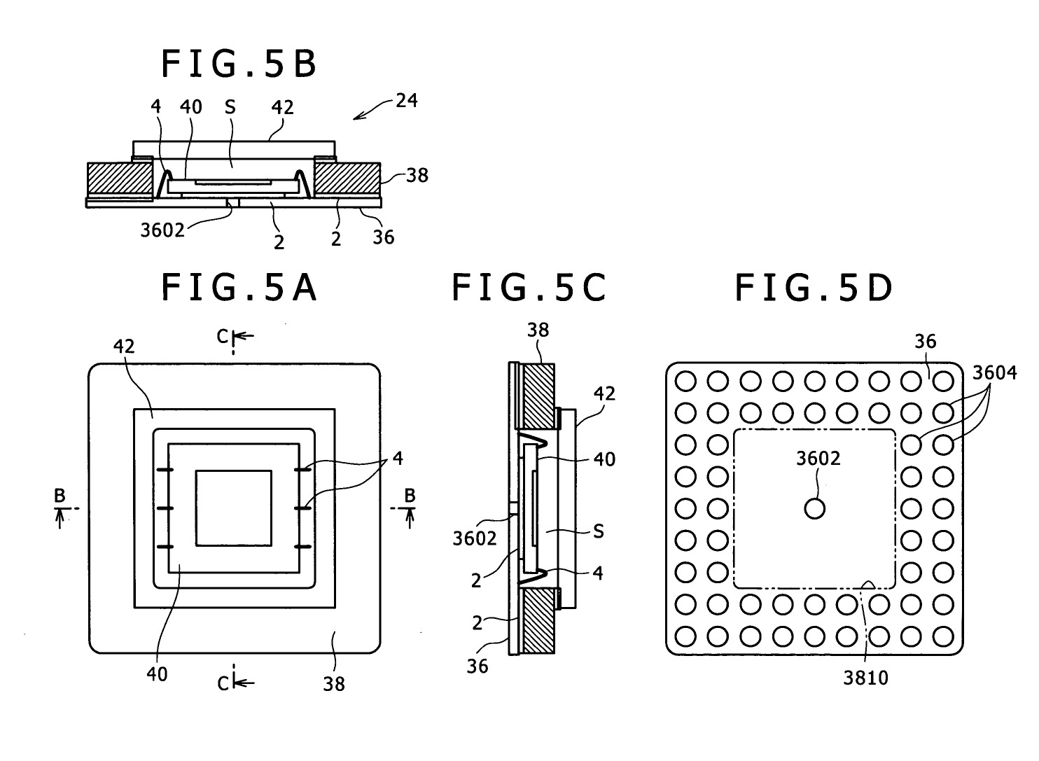

FIG. 5A is a plan view of an image pickup apparatus 24, FIG. 5B is a cross sectional view taken along line B-B of FIG. 5A, FIG. 5C is a cross sectional view taken along line C-C of FIG. 5A, and FIG. 5D is a perspective view as viewed in the direction indicated by D in FIG. 5A. Referring now to FIGS. 5A to 5D, the image pickup apparatus 24 includes a wiring board 36, a frame member 38, an image pickup element 40, and a transparent cover 42. The frame member 38 is disposed on the wiring board 36, and the image pickup element 40 is disposed on the wiring board 36 on the inner side of the frame member 38. The transparent cover 42 is disposed on the frame member 38.

The image pickup element 40 picks up an image of an image pickup object formed by the image pickup optical system 23 to produce an image pickup signal. The image pickup element 40 may be formed from a CCD unit, a CMOS sensor or some other known sensor.

The image pickup element 40 has a form of a rectangular plate and has an upper face and a lower face on the opposite sides in a thicknesswise direction thereof. A rectangular image pickup face of a size smaller than the contour of the upper face of the image pickup element 40 is formed at a central portion of the upper face of the image pickup element 40. A plurality of electrodes for wiring for extracting an image pickup signal and so forth are formed on the upper face of a portion of the image pickup element 40 which has a shape of a framework surrounding the image pickup face.

The wiring board 36 has an area greater than that of the contour of the lower face of the image pickup element 40. The image pickup element 40 is placed at the lower face thereof on the upper face of the wiring board 36 and adhered by thermosetting adhesive 2.

A plurality of electrodes not shown made of a conductive material and wiring patterns not shown connected to the electrodes are formed on the upper face of the wiring board 36.

Further, as seen in FIG. 5D, a plurality of soldering lands 3604 are formed on the lower face of the wiring board 36. The soldering lands 3604 are connected to the wiring patterns of the wiring board 36 and connected by soldering to the base plate 26.

For the wiring board 36, a flexible wiring board made of polyimide as a base material or a thin organic substrate made of glass cloth can be used.

As seen in FIGS. 5A to 5C, the electrodes of the image pickup element 40 and the electrodes of the wiring board 36 are electrically connected to each other by wires 4 bonded thereto.

One or a plurality of through-holes 3602 are formed at a suitable location or locations of the wiring board 36 opposing to the lower face of the image pickup element 40.

It is to be noted that a hard layer of a copper pattern or the like may be provided on the lower face of the image pickup element 40 opposing to the electrodes provided on the upper face of the wiring board 36 so that enhancement of the wire bonding performance to the electrodes hereinafter described may be achieved advantageously.

The frame member 38 has a shape of a rectangular framework having an accommodating space S which has a contour greater than the image pickup element 40 so that the image pickup element 40 can be accommodated inside the frame member 38. In the present embodiment, the wiring board 36 and the frame member 38 have contours same as each other.

The frame member 38 has an upper face and a lower face on the opposite sides in the thicknesswise direction thereof. The frame member 38 is placed at the lower face thereof on the upper face of the wiring board 36 and adhered by the thermosetting adhesive 2 such that the frame member 38 covers the outer side of the image pickup element 40.

It is to be noted that the thermosetting adhesive 2 is provided in such a shape and an amount that the through-holes 3602 and the accommodating space S communicate with each other.

Further, in the present embodiment, soldering lands 3604 of the wiring board 36 are provided on a face of the wiring board 36 positioned on the opposite side to the face of the wiring board 36 to which the image pickup element 40 and the frame member 38 are attached as seen in FIG. 5D. The soldering lands 3604 are disposed within a range of the contour 3610 of the frame member 38.

The frame member 38 is made of a material having a coefficient of thermal expansion lower than that of the wiring board 36 and having a rigidity higher than that of the wiring board 36.

For example, the coefficient of thermal expansion of the frame member 38 is lower than ½ that of the wiring board 36.

The frame member 38 has rigidity different from that of the wiring board 36 by such a degree that, where the frame member 38 and the wiring board 36 are coupled to each other by the thermosetting adhesive 2, even if warpage or twist tends to occur with the wiring board 36, the frame member 38 resists to prevent such deformation as warpage or twist.

As the material of the frame member 38, for example, a ceramic material or a metal material can be used. As the metal material, 42-alloy or Kovar can be adopted.

The following particular examples can be adopted for the wiring board 36 and the frame member 38.

The wiring board 36 may be formed as a flexible wiring board of a coefficient of linear expansion of 32×10⁻⁶ and an elastic modulus of 3.2 GPa while the frame member 38 is made of a ceramic material having a coefficient of linear expansion of 7.2×10⁻⁶ and an elastic modulus of 270 GPa.

The transparent cover 42 is formed as a rectangular plate which can close up the accommodating space S and is placed on and adhered to an upper face of the frame member 38 by the thermosetting adhesive 2 so that the image pickup element 40 is enclosed in the accommodating space S.

The transparent cover 42 may be made of any material which transmits light therethrough to the image pickup face of the image pickup element 40 and particularly made of a transparent glass material or a transparent synthetic resin material.

Now, two examples of a fabrication method are described.

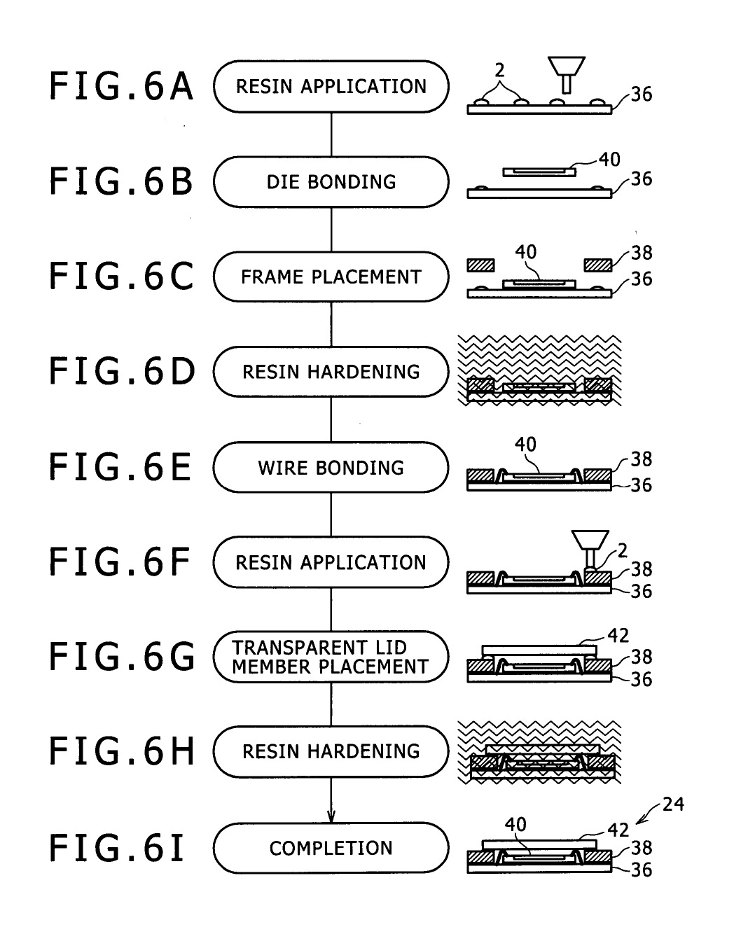

FIGS. 6A to 6I illustrate a first fabrication method for the image pickup apparatus 24.

First, thermosetting adhesive 2 is applied to locations of an upper face of a wiring board 36 corresponding to the image pickup element 40 and the frame member 38 as seen in FIG. 6A (resin application).

Then, an image pickup element 40 is positioned and placed on the upper face of the wiring board 36 as seen in FIG. 6B (die bonding).

Thereafter, a frame member 38 is positioned and placed on the upper face of the wiring board 36 as seen in FIG. 6C (frame placement).

Then, the image pickup element 40 and the frame member 38 placed on the upper face of the wiring board 36 are heated in this state in a heating chamber H (or a heating furnace or an oven) to thermally harden the thermosetting adhesive 2 to securely adhere the image pickup element 40 and the frame member 38 to the upper face of the wiring board 36 as seen in FIG. 6D (resin hardening).

Thereafter, the image pickup element 40 and the frame member 38 secured to the upper face of the wiring board 36 are taken out from the heating chamber H, and the electrodes on the upper face of the wiring board 36 and the electrodes on the upper face of the image pickup element 40 are electrically connected to each other using wires 4 as seen in FIG. 6E (wire bonding).

Then, thermosetting adhesive 2 is applied to the upper face of the frame member 38 as seen in FIG. 6F (resin application).

Then, a transparent cover 42 is placed on the upper face of the frame member 38 as seen in FIG. 6G (transparent lid member placement).

Thereafter, the transparent cover 42 placed on the upper face frame member 38 is heated in this state in the heating chamber H to thermally harden the thermosetting adhesive 2 to adhere and secure the frame member 38 and the transparent cover 42 to each other as seen in FIG. 6H (resin hardening).

Finally, the transparent cover 42 secured to the frame member 38 is taken out from the heating chamber H, and consequently, an image pickup apparatus 24 is completed as seen in FIG. 6I (completion).

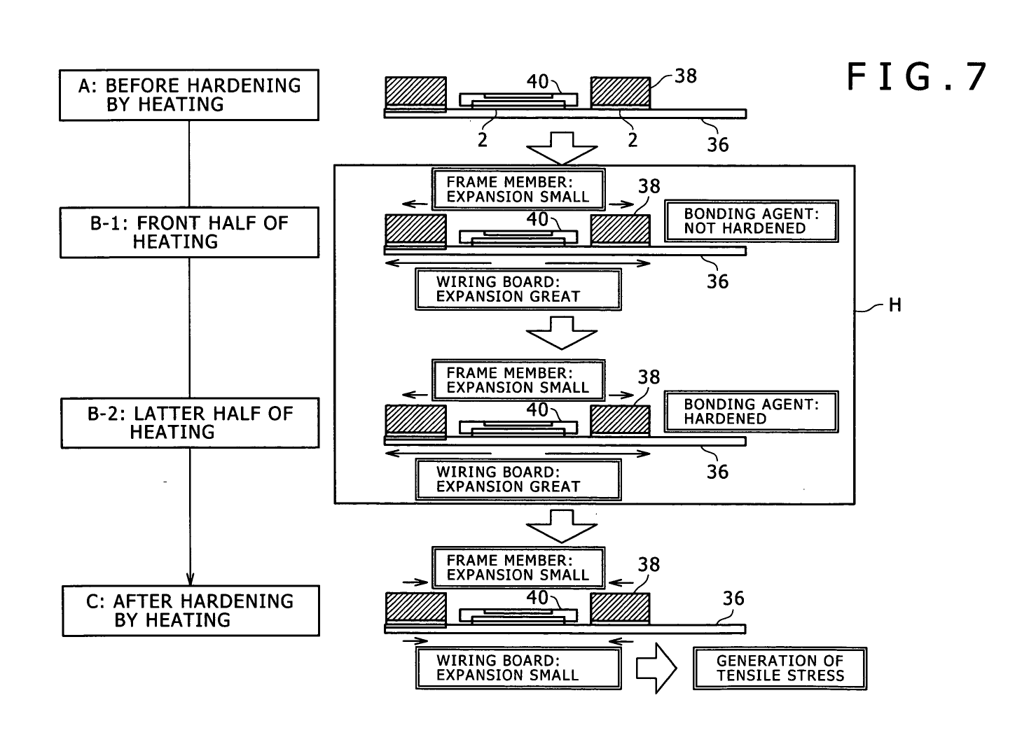

Now, action and effects of the present invention are described with reference to FIGS. 7A to 7D.

FIG. 7 illustrates a principle when the frame member 38 and the image pickup element 40 are adhered and secured to the wiring board 36 by the thermosetting adhesive 2 and illustrates the resin hardening step of FIG. 6D and situations around the resin hardening step.

As seen in A of FIG. 7, prior to the resin hardening by heating, the frame member 38 and the image pickup element 40 are placed on the upper face of the wiring board 36 with the thermosetting adhesive 2 interposed therebetween.

Then, as seen in B-1 of FIG. 7, in the front half of the heating, the thermosetting adhesive 2 is not heated sufficiently as yet and hence is not in a hardened state.

Meanwhile, by the heating, both of the wiring board 36 and the frame member 38 expand in proportion to the respective coefficients of thermal expansion thereof. However, since the coefficient of thermal expansion of the frame member 38 is lower than that of the wiring board 36, the expansion amount of the wiring board 36 is greater than that of the frame member 38.

Then, as seen in B-2 of FIG. 7, in the latter half of the heating, the thermosetting adhesive 2 is heated and hardened while the wiring board 36 and the frame member 38 are in the respectively expanded states so that the frame member 38 and the image pickup element 40 are secured to the upper face of the wiring board 36.

Then, as seen in C of FIG. 7, when the temperature drops after the resin hardening by heating, both of the wiring board 36 and the frame member 38 tend to contract in proportion to the respective coefficients of thermal expansion. However, since the frame member 38 has a lower coefficient of thermal expansion than the wiring board 36 and has a rigidity higher than the wiring board 36, the wiring board 36 may not contract in response to the coefficient of thermal expansion thereof, but peripheral portions of the wiring board 36 are pulled by the frame member 38 through the thermosetting adhesive 2. Thus, the wiring board 36 is placed in a state wherein tensile stress is applied thereto.

Accordingly, even if the tensile stress tends to produce warpage or twist on the wiring board 36, the frame member 38 resists to prevent such deformation as warpage or twist. Consequently, the wiring board 36 is maintained in a flattened state.

Accordingly, according to the present embodiment, even if a material having a small thickness and a low rigidity is used for the wiring board 36 of the image pickup apparatus 24, the wiring board 36 does not suffer from warpage or twist, and flatness of the wiring board 36 can be achieved.

This is advantageous in achievement of reduction of distortion of the image pickup element 40, assurance of enhancement of the wire bonding performance, and enhancement of the soldering coupling performance and also in enhancement of the reliability, miniaturization, reduction in thickness and reduction in weight of the image pickup apparatus 24.

Further, in the present embodiment, since the thermosetting adhesive 2 is used in order to adhere the frame member 38 and the image pickup element 40 to the wiring board 36, the frame member 38 and the image pickup element 40 can be coupled simultaneously to the wiring board 36 by one heating cycle. Consequently, the hardening steps for them can be performed by a common hardening step, and therefore, reduction of the tact and reduction of the number of man-hours can be achieved.

Further, in the present embodiment, the through-holes 3602 are provided in the wiring board 36 to establish communication between the accommodating space S in which the image pickup element 40 is disposed and the outside of the frame member 38. Therefore, no difference in environment occurs between the accommodating space S and the outside of the frame member 38, which is advantageous in achievement of high reliability. It is to be noted that, if a through-hole for establishing communication between the accommodating space S and the outside of the frame member 38 is formed otherwise in the frame member 38, then the rigidity of the frame member 38 drops. However, since, in the present embodiment, there is no necessity to provide a through-hole in the frame member 38, there is an advantage in assurance of rigidity of the frame member 38.

Further, since the through-holes 3602 are provided in the wiring board 36, otherwise possible rise of the internal pressure upon hardening of the thermosetting adhesive 2 by heating can be suppressed. This is advantageous in use of the thermosetting adhesive 2 at the step of securing the transparent cover 42 to the frame member 38 by adhesion.

Furthermore, in the present embodiment, the soldering lands 3604 of the wiring board 36 are disposed within the range of the contour 3810 of the frame member 38 on the lower face of the wiring board 36, or in other words, the soldering lands 3604 of the wiring board 36 are disposed in a concentrated manner on the lower face of the frame member 38. Therefore, the soldering lands 3604 are positioned along the frame member 38, and consequently, the flatness of soldering lands 3604 can be assured readily. As a result, stabilized soldering can be anticipated, which is advantageous in achievement of enhancement of the soldering performance.

Further, since the soldering lands 3604 are provided with high rigidity together with flatness, an inspection by means of an electric checker can be performed advantageously irrespective of whether the electric checker is of the contact type or of the contactless type.

Now, the second fabrication method for the image pickup apparatus 24 is described.

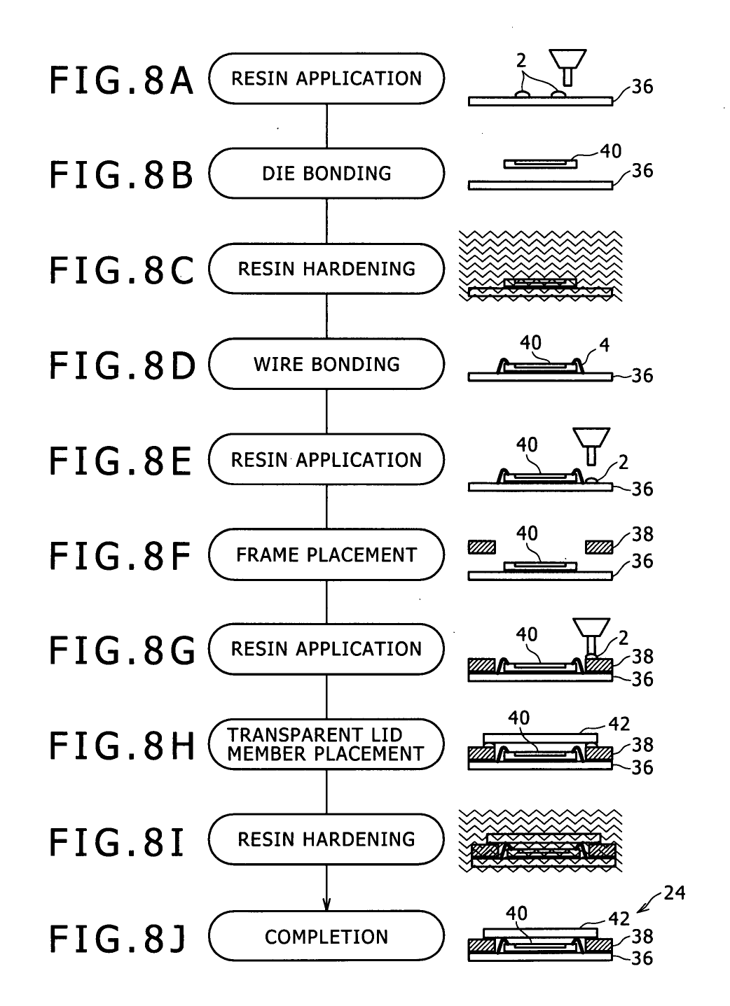

FIGS. 8A to 8I illustrate the second fabrication method for the image pickup apparatus 24.

First, thermosetting adhesive 2 is applied to locations of an upper face of a wiring board 36 corresponding to the image pickup element 40 and the frame member 38 as seen in FIG. 8A (resin application).

Then, an image pickup element 40 is positioned and placed on the upper face of the wiring board 36 as seen in FIG. 8B (die bonding).

Then, the image pickup element 40 placed on the upper face of the wiring board 36 is heated in this state in a heating chamber H (refer to A of FIG. 7) to thermally harden the thermosetting adhesive 2 to securely adhere the image pickup element 40 to the upper face of the wiring board 36 as seen in FIG. 8C (resin hardening).

Thereafter, the image pickup element 40 secured to the upper face of the wiring board 36 is taken out from the heating chamber H, and the electrodes on the upper face of the wiring board 36 and the electrodes on the upper face of the image pickup element 40 are electrically connected to each other using wires 4 as seen in FIG. 8D (wire bonding).

Then, thermosetting adhesive 2 is applied to a location of an upper face of the wiring board 36 corresponding to the frame member 38 as seen in FIG. 8E (resin application).

Thereafter, a frame member 38 is positioned and placed on the upper face of the wiring board 36 as seen in FIG. 8F (frame placement).

Then, thermosetting adhesive 2 is applied to the upper face of the frame member 38 as seen in FIG. 8G (resin application).

Then, a transparent cover 42 is placed on the upper face of the frame member 38 as seen in FIG. 8H (transparent lid member placement).

Thereafter, the transparent cover 42 is placed on the upper face of the frame member 38 in the heating chamber H and is heated in this state in the heating chamber H to thermally harden the thermosetting adhesive 2 to adhere and secure the frame member 38 to the upper face of the wiring board 36 as seen in FIG. 8I (resin hardening).

Finally, the transparent cover 42 secured to the frame member 38 is taken out from the heating chamber H, and consequently, an image pickup apparatus 24 is completed as seen in FIG. 8J (completion).

Also the image pickup apparatus 24 fabricated by such a second fabrication process as described above exhibits advantages similar to those exhibited by the image pickup apparatus 24 fabricated by the first fabrication process.

It is to be noted that, in the first fabrication process described hereinabove, since wire bonding is performed on the inner side of the frame member 38 after the frame member 38 is secured to the wiring board 36 by adhesion, it is necessary to assure the space between the image pickup element 40 and the frame member 38.

In contrast, in the second fabrication process, since the frame member 38 is secured to the wiring board 36 by adhesion (FIG. 8I) after the wire bonding (FIG. 8D), the space between the image pickup element 40 and the frame member 38 can be reduced from that in the first fabrication process. In other words, the distance between the second bonding points (electrodes of the image pickup element 40) of the wire bonding and the inner wall of the frame member 38 can be reduced. This is advantageous in miniaturization of the frame member 38 and hence in miniaturization of the image pickup apparatus 24.

Further, in the second fabrication process, an adhesive same as the thermosetting adhesive 2 used to secure the frame member 38 to the wiring board 36 by adhesion is used as the adhesive for securing the transparent cover 42 to the frame member 38 by adhesion. Therefore, the thermosetting adhesive 2 can be hardened at a time in FIG. 8I. Accordingly, it is possible to moderate the stress to be applied to the frame member 38 or the transparent cover 42, which is advantageous in assurance of the reliability.

It is to be noted that, while, in the embodiments described above, the wiring board 36 and the frame member 38 have the same contour, otherwise the wiring board 36 may have a size greater than that of the frame member 38. In this instance, the flatness of the wiring board 36 can be assured within the range within which the frame member 38 is attached.

Further, in the embodiments described above, the soldering lands 3604 are provided on the wiring board 36 and are soldered to the wiring board 36 so that an image pickup signal or the like produced by the image pickup element 40 of the image pickup apparatus 24 can be supplied to the base plate 26. However, according to the present invention, the countermeasure for supplying such an image pickup signal or the like as mentioned above is not limited to this. For example, in place of provision of the soldering lands 3604, a connector may be provided at a lead portion extending like a belt from the wiring board 36 such that an image signal or the like is provided from the wiring board 36 to the base plate 26 through the connector.

Further, in the embodiments described above, the electronic device is the portable telephone set 10. However, the present invention can be applied widely, for example, to portable information terminals such as a PDA or a notebook type computer and various camera apparatus such as a digital still camera and a video camera.

It should be understood by those skilled in the art that various modifications, combinations, sub-combinations and alterations may occur depending on design requirements and other factors insofar as they are within the scope of the appended claims or the equivalents thereof.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. An image pickup apparatus comprising:
a wiring board;
a frame member having a framework-like shape and disposed on said wiring board;
an image pickup element disposed on the inner side of said frame member on said wiring board; and
a transparent cover disposed on said frame member, wherein
said wiring board and said frame member are attached to each other by thermosetting adhesive, and
said frame member is made of a material which has a coefficient of thermal expansion lower than that of said wiring board and has a rigidity higher than that of said wiring board.

2. The image pickup apparatus according to claim 1, wherein said wiring board and said image pickup element, and said frame member and said transparent cover, are attached to each other individually by the thermosetting adhesive.

3. The image pickup apparatus according to claim 1, wherein soldering land portions are provided on a face of said wiring board opposite to the face to which said image pickup element and said frame member are attached, and are disposed within a range of a contour of said frame member.

4. A camera module comprising:
a lens barrel configured to hold an image pickup optical system;
a base plate attached to said lens barrel;
an image pickup apparatus incorporated in said lens barrel and configured to pick up an image of an image pickup object formed by said image pickup optical system and output an image pickup signal; and
a signal processing section provided on said base plate and configured to receive the image pickup signal outputted from said image pickup apparatus as an input and perform a predetermined signal process for the received image pickup signal;
said image pickup apparatus including
a wiring board,
a frame member having a framework-like shape and disposed on said wiring board,
an image pickup element disposed on the inner side of said frame member on said wiring board, and
a transparent cover disposed on said frame member, wherein
said wiring board and said frame member are attached to each other by a thermosetting adhesive, and
said frame member is made of a material which has a coefficient of thermal expansion lower than that of said wiring board and has a rigidity higher than that of said wiring board.

5. An electronic device comprising:
a housing; and
a camera module incorporated in said housing;
said camera module including
a lens barrel configured to hold an image pickup optical system,
a base plate attached to said lens barrel,
an image pickup apparatus incorporated in said lens barrel and configured to pick up an image of an image pickup object formed by said image pickup optical system and output an image pickup signal, and
a signal processing section provided on said base plate and configured to receive the image pickup signal outputted from said image pickup apparatus as an input and perform a predetermined signal process for the received image pickup signal,
said image pickup apparatus including
a wiring board,
a frame member having a framework-like shape and disposed on said wiring board,
an image pickup element disposed on the inner side of said frame member on said wiring board, and
a transparent cover disposed on said frame member, wherein
said wiring board and said frame member are attached to each other by a thermosetting adhesive, and
said frame member is made of a material which has a coefficient of thermal expansion lower than that of said wiring board and has a rigidity higher than that of said wiring board.

6. A fabrication method for an image pickup apparatus which includes
a wiring board,
a frame member having a framework-like shape and disposed on the wiring board,
an image pickup element disposed on the inner side of the frame member on the wiring board, and
a transparent cover disposed on the frame member, wherein
the wiring board and the frame member are attached to each other by thermosetting adhesive, the fabrication method comprising:
forming the frame member from a material which has a coefficient of thermal expansion lower than that of the wiring board and has a rigidity higher than that of the wiring board; and
placing the frame member on the wiring board with the thermosetting adhesive interposed and heating the frame member in this state to harden the thermosetting adhesive.

7. The fabrication method for an image pickup apparatus according to claim 6, wherein, when the frame member is attached to the wiring board by hardening of the thermosetting adhesive, the image pickup element is attached to the wiring board simultaneously by the thermosetting adhesive, and then the image pickup element and electrodes on the wiring board are connected to each other by wire bonding, whereafter the transparent cover is placed on the frame member with the thermosetting adhesive interposed, and then the transparent cover placed on the frame member is heated in this state to harden the thermosetting adhesive to attach the transparent cover to the frame member.

8. The fabrication method for an image pickup apparatus according to claim 6, wherein, before the frame member is attached to the wiring board by hardening of the thermosetting adhesive, the image pickup element is attached to the wiring board by the thermosetting adhesive, and then the image pickup element and electrodes on the wiring board are connected to each other by wire bonding, whereafter the frame member is attached and simultaneously the transparent cover is placed on the frame member with the thermosetting adhesive interposed and is then heated to harden the thermosetting adhesive to attach the transparent cover to the frame member.
